(19) United States
(12) Patent Application Publication
(10) Pub. No.: US 2026/0231465 A1
(43) Pub. Date: Aug. 6, 2026

(54) SEMICONDUCTOR DEVICE

(71) Applicant: KABUSHIKI KAISHA TOSHIBA, Kawasaki-shi (JP)

(72) Inventors: Hiro GANGI, Marugame Kagawa (JP); Yusuke KOBAYASHI, Yokohama Kanagawa (JP)

(73) Assignee: KABUSHIKI KAISHA TOSHIBA, Kawasaki-shi (JP)

(21) Appl. No.: 19/407,078

(22) Filed: Dec. 3, 2025

(30) Foreign Application Priority Data
Jan. 31, 2025 (JP) 2025-015317

(51) Int. Cl. H10D 30/63; H10D 62/10; H10D 62/60; H10D 64/00; H10D 64/23; H10D 64/27; H10D 64/68

(52) U.S. Cl. CPC H10D 30/63; H10D 62/124; H10D 62/60; H10D 64/112; H10D 64/117; H10D 64/2527; H10D 64/513; H10D 64/685; H10D 64/691; H10D 64/693; H10D 62/102

(57) ABSTRACT

According to one embodiment, a semiconductor device includes first to third electrodes, first and second conductive members, semiconductor member, first and second insulating members. The third electrode is located between the first electrode and the second electrode. The first conductive member is electrically connected with the second electrode. A second impurity concentration of the first conductivity type of the second semiconductor region is greater than a first impurity concentration of the first conductivity type of the first semiconductor region. The first insulating member includes first to fourth insulating regions. At least a part of the first insulating region is between the third electrode and the semiconductor member. A relative dielectric constant of the second insulating member is greater than a relative dielectric constant of the first insulating member.

### CROSS-REFERENCE TO RELATED APPLICATIONS

This application is based upon and claims the benefit of priority from Japanese Patent Application No. 2025-015317, filed on Jan. 31, 2025; the entire contents of which are incorporated herein by reference.

### FIELD

Embodiments described herein relate generally to a semiconductor device.

### BACKGROUND

For example, it is desirable to improve characteristics of a semiconductor device such as a transistor or the like.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating a semiconductor device according to the first embodiment;

FIG. 3 is a schematic cross-sectional view illustrating a semiconductor device according to the first embodiment;

FIG. 4 is a schematic cross-sectional view illustrating a semiconductor device according to the first embodiment;

FIG. 5 is a schematic cross-sectional view illustrating a semiconductor device according to the first embodiment;

FIG. 6 is a schematic cross-sectional view illustrating a semiconductor device according to a second embodiment;

FIG. 7 is a schematic cross-sectional view illustrating a semiconductor device according to the second embodiment; and

FIG. 8 is a schematic perspective view illustrating a semiconductor device according to a third embodiment.

### DETAILED DESCRIPTION

According to one embodiment, a semiconductor device includes a first electrode, a second electrode, a third electrode, a first conductive member, a second conductive member, a semiconductor member, a first insulating member, and a second insulating member. A direction from the first electrode toward the second electrode is along a first direction. The third electrode is located between the first electrode and the second electrode in the first direction. The first conductive member is configured to be electrically connected with the second electrode. A position in the first direction of the first conductive member is between a first electrode position in the first direction of the first electrode and a third electrode position in the first direction of the third electrode. The semiconductor member includes a first semiconductor region and a second semiconductor region, the first semiconductor region and the second semiconductor region being of a first conductivity type. A second impurity concentration of the first conductivity type of the second semiconductor region is greater than a first impurity concentration of the first conductivity type of the first semiconductor region. The first semiconductor region includes a first partial region and a second partial region. The first partial region is between the first electrode and the first conductive member in the first direction. A direction from the first conductive member toward the second partial region is along a second direction crossing the first direction. The second semiconductor region is between the second partial region and the second electrode in the first direction. A direction from the third electrode toward the second semiconductor region is along the second direction. The second conductive member is located between the first partial region and the first conductive member in the first direction. The second conductive member is electrically insulated from the second electrode. The first insulating region member includes a first insulating region, a second insulating region, a third insulating region, and a fourth insulating region. At least a part of the first insulating region is between the third electrode and the semiconductor member. At least a part of the second insulating region is between the first conductive member and the semiconductor member. At least a part of the third insulating region is between the second conductive member and the semiconductor member. At least a part of the fourth insulating region is between the first conductive member and the third electrode. The second insulating member includes a first insulating portion. The first insulating portion is between the second conductive member and the first conductive member. A second relative dielectric constant of the second insulating member is greater than a first relative dielectric constant of the first insulating member.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

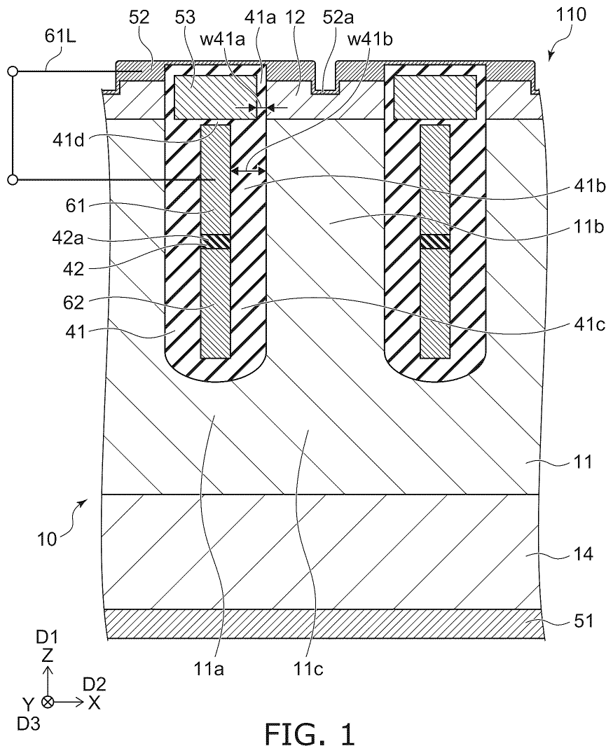

FIG. 1 is a schematic cross-sectional view illustrating a semiconductor device according to a first embodiment.

As shown in FIG. 1, the semiconductor device 110 according to the embodiment includes a first electrode 51, a second electrode 52, a third electrode 53, a first conductive member 61, a second conductive member 62, a semiconductor member 10, a first insulating member 41, and a second insulating member 42.

The direction from the first electrode 51 toward the second electrode 52 is along a first direction D1. The first direction D1 is taken as a Z-axis direction. A direction perpendicular to the Z-axis direction is taken as an X-axis direction. A direction perpendicular to the Z-axis direction and the X-axis direction is taken as a Y-axis direction.

The third electrode 53 is between the first electrode 51 and the second electrode 52 in the first direction D1.

The position (a first conductive member position) in the first direction D1 of the first conductive member 61 is between the position (a first electrode position) in the first direction D1 of the first electrode 51 and the position (a third electrode position) in the first direction D1 of the third electrode 53. In the example, the first conductive member 61 is between the first electrode 51 and the third electrode 53 in the first direction D1.

The first conductive member 61 is configured to be electrically connected with the second electrode 52. As shown in FIG. 1, the first conductive member 61 may be electrically connected with the second electrode 52 by a wiring part 61L, etc. The position of the wiring part 61L may be different from the position of the wiring part 61L in the cross section shown in FIG. 1.

The semiconductor member 10 includes a first semiconductor region 11 of a first conductivity type and a second semiconductor region 12 of the first conductivity type. As described below, the semiconductor member 10 may further include a semiconductor region of a second conductivity type. The first conductivity type is one of an n-type or a p-type. The second conductivity type is the other of the n-type or the p-type. Herein, the first conductivity type is taken to be the n-type; and the second conductivity type is taken to be the p-type.

The first-conductivity-type impurity concentration (a second impurity concentration) of the second semiconductor region 12 is greater than the first-conductivity-type impurity concentration (a first impurity concentration) of the first semiconductor region 11.

As shown in FIG. 1, the first semiconductor region 11 includes a first partial region 11a and a second partial region 11b. The first partial region 11a is between the first electrode 51 and the first conductive member 61 in the first direction D1. The direction from the first conductive member 61 toward the second partial region 11b is along a second direction D2. The second direction D2 may be, for example, the X-axis direction. The second direction D2 crosses the first direction D1.

The second semiconductor region 12 is between the second partial region 11b and the second electrode 52 in the first direction D1. The direction from the third electrode 53 toward the second semiconductor region 12 is along the second direction D2. For example, the second electrode 52 is electrically connected with the second semiconductor region 12.

As shown in FIG. 1, the second conductive member 62 is between the first partial region 11a and the first conductive member 61 in the first direction D1. The second conductive member 62 is electrically insulated from the second electrode 52.

The first insulating member 41 includes a first insulating region 41a, a second insulating region 41b, a third insulating region 41c, and a fourth insulating region 41d. At least a part of the first insulating region 41a is between the third electrode 53 and the semiconductor member 10 in the second direction D2. At least a part of the second insulating region 41b is between the first conductive member 61 and the semiconductor member 10. At least a part of the third insulating region 41c is between the second conductive member 62 and the semiconductor member 10. At least a part of the fourth insulating region 41d is between the first conductive member 61 and the third electrode 53.

The second insulating member 42 includes a first insulating portion 42a. The first insulating portion 42a is between the second conductive member 62 and the first conductive member 61. The relative dielectric constant (a second relative dielectric constant) of the second insulating member 42 is different from the relative dielectric constant (a first relative dielectric constant) of the first insulating member 41. The second relative dielectric constant is greater than the first relative dielectric constant.

For example, a current that flows between the first electrode 51 and the second electrode 52 can be controlled by the potential of the third electrode 53. The potential of the third electrode 53 may be, for example, a potential referenced to the potential of the second electrode 52. For example, the first electrode 51 functions as a drain electrode. For example, the second electrode 52 functions as a source electrode. For example, the third electrode 53 functions as a gate electrode. For example, the first insulating region 41a functions as a gate insulating film. The semiconductor device 110 is, for example, a transistor.

The first conductive member 61 and the second conductive member 62 function as field plates. The first conductive member 61 is a source-potential field plate. For example, the second conductive member 62 functions as a floating field plate. These field plates suppress local concentration of electric fields. For example, a leakage current is suppressed. For example, a high breakdown voltage is obtained.

The second conductive member 62 is capacitively coupled with the first conductive member 61 via the first insulating portion 42a. The potential of the second conductive member 62 is appropriately controlled, and concentration of the electric field is suppressed.

As shown in FIG. 1, the semiconductor member 10 may further include a fourth semiconductor region 14 of the first conductivity type. The fourth semiconductor region 14 is between the first electrode 51 and the first semiconductor region 11. The first-conductivity-type impurity concentration of the fourth semiconductor region 14 is greater than the first-conductivity-type impurity concentration of the first semiconductor region 11. The fourth semiconductor region 14 may be, for example, an n-type semiconductor substrate. A stable electrical connection is obtained between the first electrode 51 and the semiconductor member 10.

According to the embodiment as described above, the relative dielectric constant of the second insulating member 42 is greater than the relative dielectric constant of the first insulating member 41. A different material from the first insulating member 41 may be used as the material of the second insulating member 42. In one example, the relative dielectric constant of the second insulating member 42 is greater than the relative dielectric constant of the first insulating member 41. A high dielectric constant material is used as the second insulating member 42.

As a result, even when the counter area between the second conductive member 62 and the first conductive member 61 (e.g., the width along the second direction D2) is reduced, the electrostatic capacitance value between the second conductive member 62 and the first conductive member 61 can be maintained at the target. Even when the widths along the second direction D2 of the counter surfaces of the second and first conductive members 62 and 61 are reduced, the target capacitive coupling can be maintained.

According to the embodiment, the widths along the second direction D2 of the counter surfaces of the second and first conductive members 62 and 61 can be reduced. Even when the width of one element is reduced, the target characteristics are obtained. The current path width per chip area can be enlarged. For example, a low on-resistance is obtained. According to the embodiment, a semiconductor device can be provided in which characteristics can be improved.

For example, in a first reference example, the relative dielectric constant of the second insulating member 42 is equal to the relative dielectric constant of the first insulating member 41. The on-resistance according to the embodiment is about 68% of the on-resistance in the first reference example. Thus, by setting the relative dielectric constant of the second insulating member 42 to be greater than the relative dielectric constant of the first insulating member 41, a semiconductor device can be provided in which characteristics can be improved.

For example, in a second reference example, both the first and second insulating members 41 and 42 include a high dielectric constant material. In such a case, the thickness (the length along the second direction D2) of the second insulating region 41b or the third insulating region 41c is increased to maintain the target characteristics. It is therefore difficult to reduce the width of one element and obtain a low on-resistance.

For example, the relative dielectric constant (the second relative dielectric constant) of the second insulating member 42 may be not less than 1.5 times the relative dielectric constant (the first relative dielectric constant) of the first insulating member 41.

When the second relative dielectric constant is greater than the first relative dielectric constant, the second insulating member 42 may include, for example, the following first compound. The first compound includes, for example, at least one selected from the group consisting of Si₃N₄, Al₂O₃, TiO₂, Ta₂O₅, SrTiO₃, LiNbO₃, Nb₂O₅, LaCuO₃, Pr₂O₃, LaAlO₃, La₂O₃, ZrO₂, HfO₂, HfSiO₄, Ce₂O₃, CeO₂, Sm₂O₃, Y₂O₃, Lu₂O₃, BaO, CaO, MgO, ZrSiO₄, BaTiO₃, TiSiO₄, and ZrTiSiO. The first compound may include, for example, a silicate including Zr and Ti. A high relative dielectric constant is stably obtained.

According to the embodiment, the second relative dielectric constant may be, for example, not less than 3.9 and not more than 67.8.

According to the embodiment, the first insulating member 41 may include, for example, at least one selected from the group consisting of silicon oxide, silicon nitride, and silicon oxynitride. The first insulating member 41 may include, for example, silicon dioxide. Good insulating characteristics are obtained. Highly stable characteristics are obtained.

In the semiconductor device 110, at least a part of the second electrode 52 has a Schottky contact with the semiconductor member 10. For example, the second electrode 52 includes a first electrode portion 52a. The first electrode portion 52a has a Schottky contact with the semiconductor member 10. The semiconductor device 110 is a Schottky transistor. Losses can be suppressed. A high-speed operation is obtained.

As shown in FIG. 1, the first semiconductor region 11 may include a third partial region 11c. The direction from the first partial region 11a toward the third partial region 11c is along the second direction D2. The third partial region 11c is between the first electrode 51 and the second partial region 11b in the first direction D1. The boundary between these partial regions may be indistinct.

As shown in FIG. 1, the length along the first direction D1 of the first conductive member 61 may be greater than the length along the first direction D1 of the third electrode 53. Electric field concentration can be effectively suppressed.

A width w41a along the second direction D2 of the first insulating region 41a may be less than a width w41b along the second direction D2 of the second insulating region 41b.

In the semiconductor device 110, a first resistance value between the second conductive member 62 and the first electrode 51 is not less than 90 kΩ. A second resistance value between the second conductive member 62 and the second electrode 52 is not less than 90 kΩ. A third resistance value between the second conductive member 62 and the third electrode 53 may be not less than 90 kΩ.

For example, the configuration of the semiconductor device 110 may be manufactured by the following method. For example, a trench is formed in a member used to form the semiconductor member 10; and a member that is used to form the second conductive member 62 is formed inside the trench. Subsequently, an insulating film that is used to form the second insulating member 42 is formed. For example, the second insulating member 42 may be formed by at least one of a sol-gel process, sputtering, PLD (Pulse Laser Deposition), CVD (Chemical Vapor Deposition), MOCVD (Metal Organic Chemical Vapor Deposition), or ALD (Atomic Layer Deposition). The first insulating member 41 is formed by thermal oxidation, depositing an oxidization film, etc. The semiconductor device 110 is formed by introducing impurities, forming electrodes, etc.

In the semiconductor device 110, the third electrode 53, the first conductive member 61, and the second conductive member 62 may extend along a third direction D3. The third direction D3 may cross a plane including the first and second directions D1 and D2. The third direction D3 may be, for example, the Y-axis direction.

Multiple third electrodes 53, multiple first conductive members 61, and multiple second conductive members 62 may be arranged along the second direction D2. A low on-resistance is obtained.

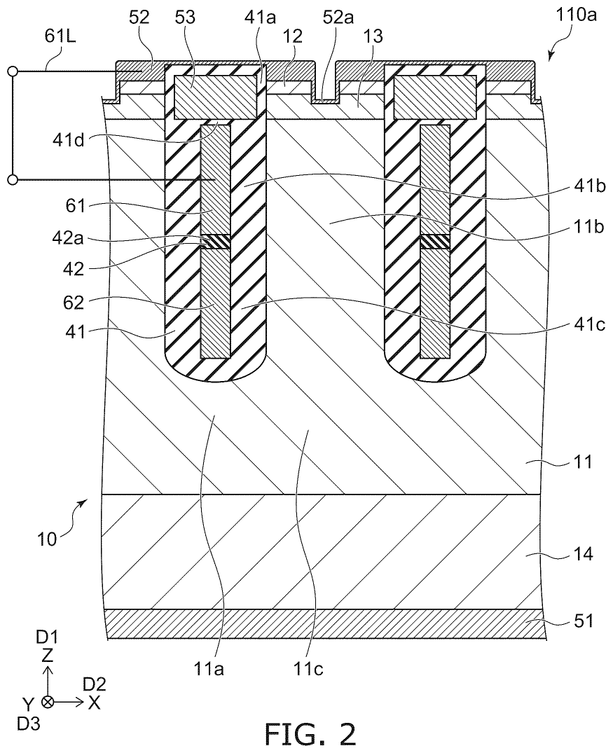

FIG. 2 is a schematic cross-sectional view illustrating a semiconductor device according to the first embodiment.

In the semiconductor device 110a according to the embodiment as shown in FIG. 2, the semiconductor member 10 includes a third semiconductor region 13. Otherwise, the configuration of the semiconductor device 110a may be similar to the configuration of the semiconductor device 110.

In the semiconductor device 110a, the semiconductor member 10 further includes the third semiconductor region 13 in addition to the first and second semiconductor regions 11 and 12. The third semiconductor region 13 is of the second conductivity type. The third semiconductor region 13 is between the second partial region 11b and the second semiconductor region 12. A part of the first insulating region 41a is between the third electrode 53 and the third semiconductor region 13 in the second direction D2. The semiconductor device 110a is, for example, an n-p-n transistor.

In the semiconductor device 110a as well, the second relative dielectric constant of the second insulating member 42 is different from the first relative dielectric constant of the first insulating member 41. For example, the second relative dielectric constant is greater than the first relative dielectric constant. The current path width per chip area can be enlarged. For example, a low on-resistance is obtained. Characteristics can be improved.

For example, the first electrode portion 52a may be electrically connected with the third semiconductor region 13. The first electrode portion 52a contacts the third semiconductor region 13. At least a part of the first electrode portion 52a is between a part of the third semiconductor region 13 and another part of the third semiconductor region 13 in the second direction D2.

Several examples related to the embodiment will now be described. In the following description, a Schottky transistor or n-p-n transistor configuration is applicable. An example in which a Schottky transistor configuration is applied will now be described.

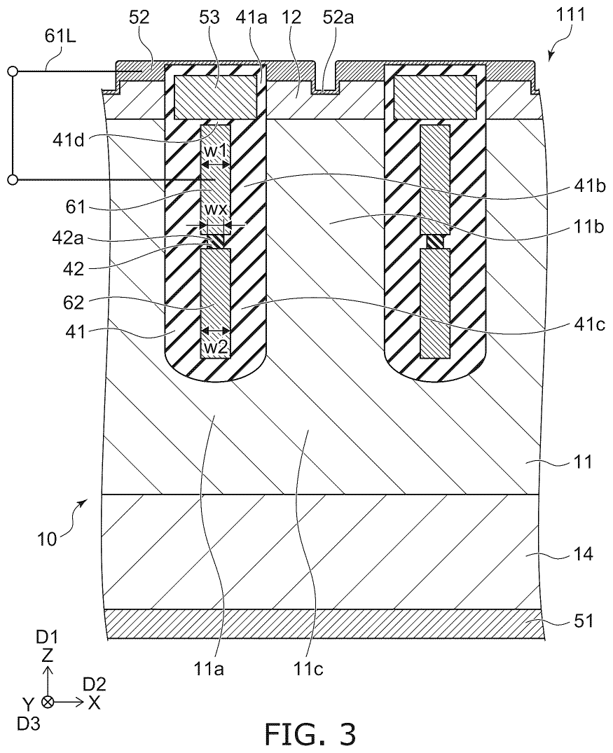

FIG. 3 is a schematic cross-sectional view illustrating a semiconductor device according to the first embodiment.

In the semiconductor device 111 according to the embodiment as shown in FIG. 3, the width of the second insulating member 42 is different from that of the semiconductor device 110 (or the semiconductor device 110a). Otherwise, the configuration of the semiconductor device 111 may be similar to the configuration of the semiconductor device 110 (or the semiconductor device 110a).

In the semiconductor device 111 as shown in FIG. 3, a width wx along the second direction D2 of the first insulating portion 42a is less than a first width w1 along the second direction D2 of the first conductive member 61. The width wx along the second direction D2 of the first insulating portion 42a is less than a second width w2 along the second direction D2 of the second conductive member 62.

In the semiconductor device 111, a part of the first insulating member 41 may be located at a part between the second conductive member 62 and the first conductive member 61. For example, the relative dielectric constant may be adjusted.

The second insulating member 42 may not be provided between the first insulating member 41 at one portion of the first insulating member 41 in the first direction D1.

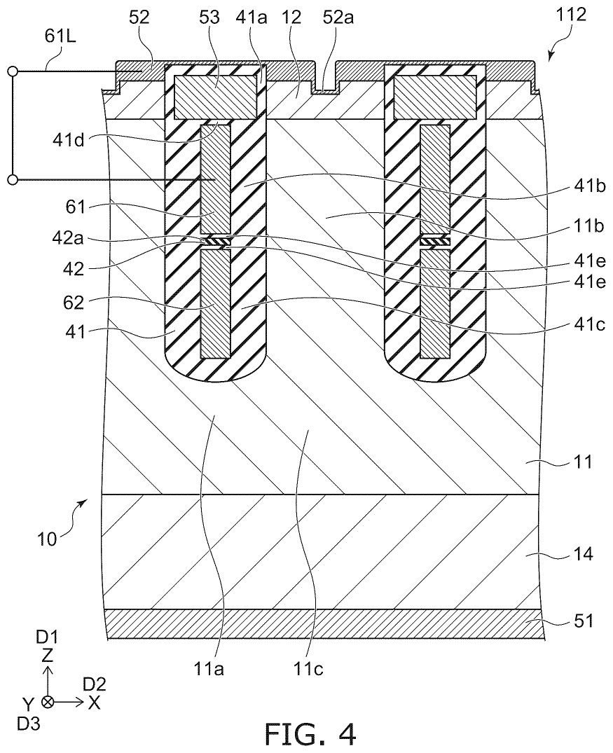

FIG. 4 is a schematic cross-sectional view illustrating a semiconductor device according to the first embodiment.

In the semiconductor device 112 according to the embodiment as shown in FIG. 4, the configuration of the second insulating member 42 is different from that of the semiconductor device 110 (or the semiconductor device 110a). Otherwise, the configuration of the semiconductor device 112 may be similar to the configuration of the semiconductor device 110 (or the semiconductor device 110a).

In the semiconductor device 112, the first insulating member 41 further includes a fifth insulating region 41e. At least a part of the fifth insulating region 41e is located at one or both of a first position between the first insulating portion 42a and the first conductive member 61 and a second position between the second conductive member 62 and the first insulating portion 42a. Thus, a low-dielectric-constant film may be between a conductive member and the second insulating member 42, which is a high-dielectric-constant film.

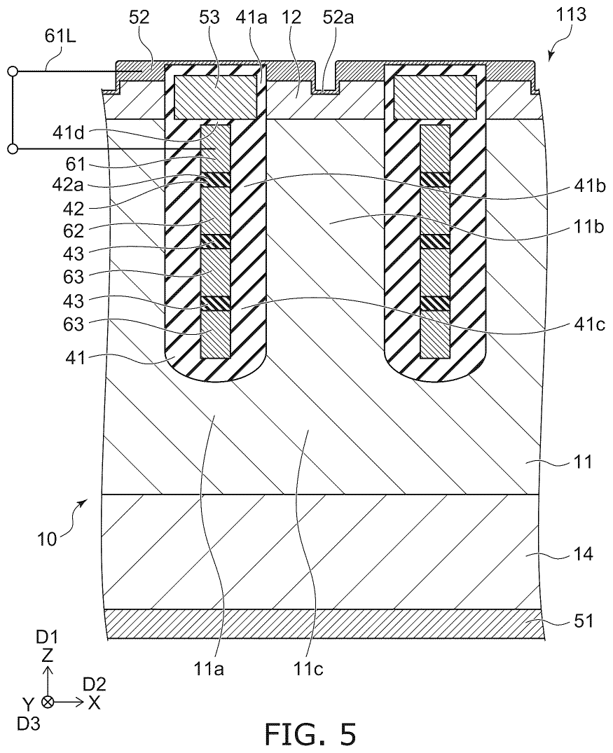

FIG. 5 is a schematic cross-sectional view illustrating a semiconductor device according to the first embodiment.

As shown in FIG. 5, the semiconductor device 113 according to the embodiment further includes a third conductive member 63. Otherwise, the configuration of the semiconductor device 113 may be similar to the configuration of the semiconductor device 110 (or the semiconductor device 110a), etc.

The semiconductor device 113 further includes the third conductive member 63 and a third insulating member 43. The third conductive member 63 is between the first partial region 11a and the second conductive member 62 in the first direction D1. At least a part of the third insulating member 43 is between the third conductive member 63 and the second conductive member 62. A third relative dielectric constant of the third insulating member 43 is different from the first relative dielectric constant. For example, the third relative dielectric constant is greater than the first relative dielectric constant. Local electric field concentration can be effectively suppressed while maintaining a narrow width of one element. A semiconductor device can be provided in which characteristics can be further improved.

The third relative dielectric constant of the third insulating member 43 may be equal to the second relative dielectric constant of the second insulating member 42. The material of the third insulating member 43 may be the same as the material of the second insulating member 42. For example, the third relative dielectric constant may be not less than 1.5 times the first relative dielectric constant.

Multiple third conductive members 63 are included in the example shown in FIG. 5. A part of the third insulating member 43 is between one of the multiple third conductive members 63 and another one of the multiple third conductive members 63.

### Second Embodiment

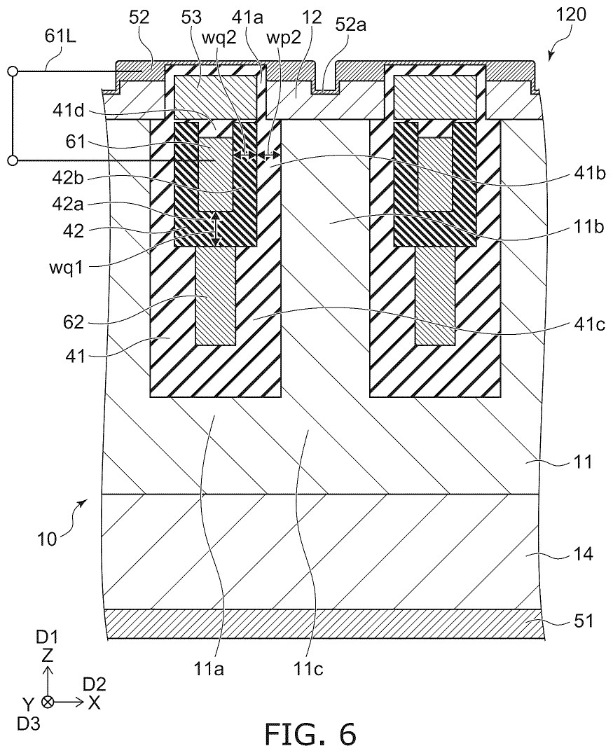

FIG. 6 is a schematic cross-sectional view illustrating a semiconductor device according to a second embodiment.

In the semiconductor device 120 according to the embodiment as shown in FIG. 6, the configuration of the second insulating member 42 is different from that of the first embodiment. Otherwise, the configuration of the semiconductor device 120 may be similar to the configuration according to the first embodiment.

In the semiconductor device 120, the second insulating member 42 further includes a second insulating portion 42b in addition to the first insulating portion 42a. The second insulating portion 42b is between the first conductive member 61 and the second insulating region 41b in the second direction D2. The first conductive member 61 is between two second insulating portions 42b in the second direction D2. In the semiconductor device 120 having such a configuration, local electric field concentration can be effectively suppressed while maintaining a narrow width of one element. A semiconductor device can be provided in which characteristics can be improved.

In the semiconductor device 120, the width along the second direction D2 of the second insulating portion 42b is taken as a second insulating portion width wq2. The width in the second direction D2 of the second insulating region 41b is taken as a second insulating region width wp2. For example, the second insulating portion width wq2 may be greater than the second insulating region width wp2. For example, electric field concentration is relaxed. For example, a high breakdown voltage is obtained.

The second insulating portion width wq2 along the second direction D2 of the second insulating portion 42b may be less than a first insulating portion thickness wq1 in the first direction D1 of the first insulating portion 42a. For example, a low on-resistance is obtained.

In one example, the direction from the fourth insulating region 41d toward a part of the second insulating portion 42b may be along the second direction D2. The fourth insulating region 41d may be between two second insulating portions 42b in the second direction D2.

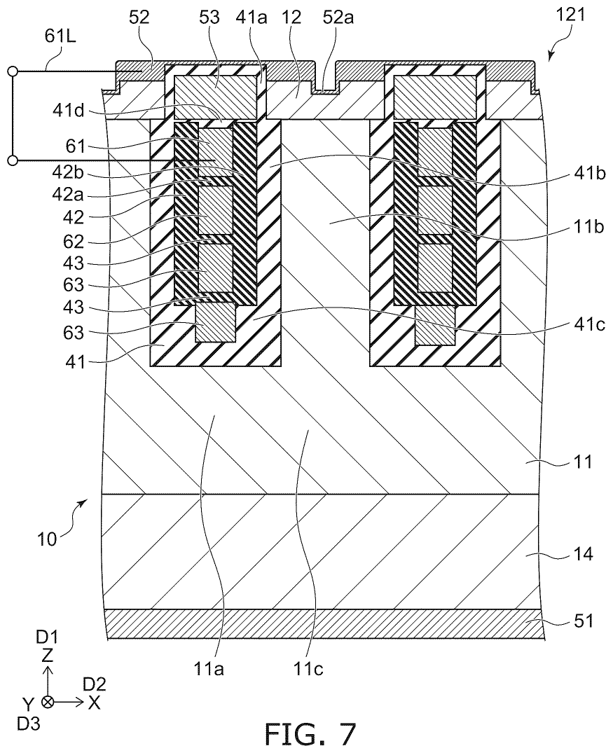

FIG. 7 is a schematic cross-sectional view illustrating a semiconductor device according to the second embodiment.

As shown in FIG. 7, the semiconductor device 121 according to the embodiment includes the third conductive member 63. Otherwise, the configuration of the semiconductor device 121 may be similar to the configuration of the semiconductor device 120.

The semiconductor device 121 includes the third conductive member 63 in addition to the first and second conductive members 61 and 62. In the example, the semiconductor device 121 includes the third insulating member 43. The third conductive member 63 is between the first partial region 11a and the second conductive member 62 in the first direction D1. At least a part of the third insulating member 43 is between the third conductive member 63 and the second conductive member 62. The third relative dielectric constant of the third insulating member 43 is different from the first relative dielectric constant. For example, the third relative dielectric constant is greater than the first relative dielectric constant.

The third relative dielectric constant of the third insulating member 43 may be equal to the second relative dielectric constant of the second insulating member 42. The material of the third insulating member 43 may be the same as the material of the second insulating member 42. The third insulating member 43 may be continuous with the second insulating member 42.

According to the first and second embodiments, for example, multiple sets that each include the third electrode 53, the first conductive member 61, and the second conductive member 62 may be provided. The multiple sets may be arranged in a plane including the second and third directions D2 and D3. Each of the multiple sets may have a dot configuration in the plane.

### Third Embodiment

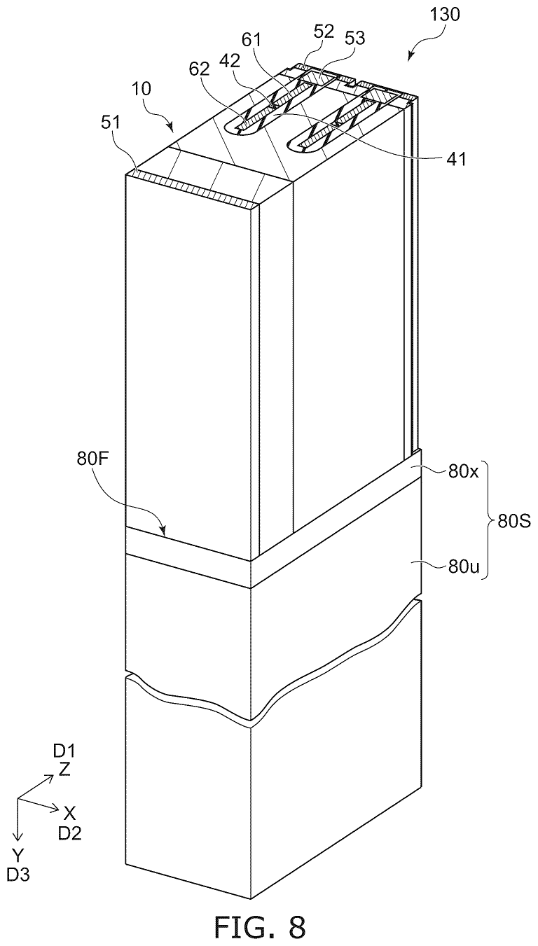

FIG. 8 is a schematic perspective view illustrating a semiconductor device according to a third embodiment.

As shown in FIG. 8, the semiconductor device according to the embodiment includes a support body 80S.

The support body 80S may be, for example, a substrate. In the example as shown in FIG. 8, the support body 80S includes a substrate portion 80u and an insulating layer 80x. The substrate portion 80u is, for example, a silicon substrate. The insulating layer 80x is on the substrate portion 80u. The insulating layer 80x is, for example, a silicon oxide layer (e.g., a thermal oxide film).

The support body 80S includes a first surface 80F. The first surface 80F is, for example, an upper surface. In the example, the first surface 80F corresponds to the upper surface of the insulating layer 80x.

The first surface 80F is along the plane including the first and second directions D1 and D2. The first surface 80F crosses the third direction D3. The first surface 80F faces the semiconductor member 10. The third electrode 53, the first conductive member 61, and the second conductive member 62 extend along the third direction D3. The third direction D3 crosses the plane including the first and second directions D1 and D2.

The semiconductor member 10 includes, for example, silicon. The semiconductor member 10 may include, for example, a compound semiconductor, etc. The first electrode 51 includes, for example, at least one selected from the group consisting of aluminum, titanium, nickel, and gold. The second electrode 52 includes, for example, at least one selected from the group consisting of aluminum, titanium, nickel, and gold. The third electrode 53, the first conductive member 61, and the second conductive member 62 include, for example, conductive silicon or polysilicon.

The first-conductivity-type impurity concentration (the first impurity concentration) of the first semiconductor region 11 may be, for example, not less than 1×10¹⁵ cm⁻³ and not more than 1×10¹⁷ cm⁻³. The first-conductivity-type impurity concentration (the second impurity concentration) of the second semiconductor region 12 may be, for example, not less than 1×10¹⁵ cm⁻³ and not more than 1×10²¹ cm⁻³. The second-conductivity-type impurity concentration (a third impurity concentration) of the third semiconductor region 13 may be, for example, not less than 1×10¹⁶ cm⁻³ and not more than 1×10¹⁸ cm⁻³. The first-conductivity-type impurity concentration (a fourth impurity concentration) of the fourth semiconductor region 14 may be, for example, not less than 1×10¹⁹ cm⁻³ and not more than ×10²¹ cm⁻³. In one example, the first impurity concentration may be not less than 1×10¹⁵ cm⁻³ but less than ××10¹⁷ cm⁻³; and the second impurity concentration may be not less than 1×10¹⁷ cm⁻³ and not more than 1×10²¹ cm⁻³.

In embodiments, information that relates to the configurations of the semiconductor regions, etc., is obtained, for example, by electron microscopy, etc. Information that relates to impurity concentrations of the semiconductor regions is obtained, for example, by EDX (Energy Dispersive X-ray Spectroscopy), SIMS (Secondary Ion Mass Spectrometry), etc. Information that relates to carrier concentrations of the semiconductor regions is obtained, for example, by SCM (Scanning Capacitance Microscopy), etc.

Embodiments may include the following technological proposals.

### Technological Proposal 1

A semiconductor device, comprising:
a first electrode;
a second electrode, a direction from the first electrode toward the second electrode being along a first direction;
a third electrode located between the first electrode and the second electrode in the first direction;
a first conductive member configured to be electrically connected with the second electrode, a position in the first direction of the first conductive member being between a first electrode position in the first direction of the first electrode and a third electrode position in the first direction of the third electrode;
a semiconductor member including a first semiconductor region and a second semiconductor region, the first semiconductor region and the second semiconductor region being of a first conductivity type, a second impurity concentration of the first conductivity type of the second semiconductor region being greater than a first impurity concentration of the first conductivity type of the first semiconductor region, the first semiconductor region including a first partial region and a second partial region, the first partial region being between the first electrode and the first conductive member in the first direction, a direction from the first conductive member toward the second partial region being along a second direction crossing the first direction, the second semiconductor region being between the second partial region and the second electrode in the first direction, a direction from the third electrode toward the second semiconductor region being along the second direction;
a second conductive member located between the first partial region and the first conductive member in the first direction, the second conductive member being electrically insulated from the second electrode;
a first insulating member including a first insulating region, a second insulating region, a third insulating region, and a fourth insulating region, at least a part of the first insulating region being between the third electrode and the semiconductor member, at least a part of the second insulating region being between the first conductive member and the semiconductor member, at least a part of the third insulating region being between the second conductive member and the semiconductor member, at least a part of the fourth insulating region being between the first conductive member and the third electrode; and
a second insulating member including a first insulating portion, the first insulating portion being between the second conductive member and the first conductive member, a second relative dielectric constant of the second insulating member being greater than a first relative dielectric constant of the first insulating member.

### Technological Proposal 2

The semiconductor device according to Technological Proposal 1, wherein
at least a part of the second electrode has a Schottky contact with the semiconductor member.

### Technological Proposal 3

The semiconductor device according to Technological Proposal 1, wherein
the semiconductor member further includes a third semiconductor region of a second conductivity type,
the third semiconductor region is between the second partial region and the second semiconductor region, and
a part of the first insulating region is between the third electrode and the third semiconductor region in the second direction.

### Technological Proposal 4

The semiconductor device according to any one of Technological Proposals 1 to 3, wherein
a width along the second direction of the first insulating portion is less than a first width along the second direction of the first conductive member, and
the width along the second direction of the first insulating portion is less than a second width along the second direction of the second conductive member.

### Technological Proposal 5

The semiconductor device according to Technological Proposal 1 or 2, wherein
the first insulating member further includes a fifth insulating region, and
at least a part of the fifth insulating region is in at least one of
a first position between the first insulating portion and the first conductive member, or
a second position between the second conductive member and the first insulating portion.

### Technological Proposal 6

The semiconductor device according to any one of Technological Proposals 1 to 5, wherein
a length along the first direction of the first conductive member is greater than a length along the first direction of the third electrode.

### Technological Proposal 7

The semiconductor device according to any one of Technological Proposals 1 to 6, Wherein
a width along the second direction of the first insulating region is less than a width along the second direction of the second insulating region.

### Technological Proposal 8

The semiconductor device according to any one of Technological Proposals 1 to 7, further comprising:
a third conductive member; and
a third insulating member,
the third conductive member being between the first partial region and the second conductive member in the first direction,
at least a part of the third insulating member being between the third conductive member and the second conductive member,
a third relative dielectric constant of the third insulating member being greater than the first relative dielectric constant.

### Technological Proposal pb 9

The semiconductor device according to Technological Proposal 8, wherein
the third relative dielectric constant is not less than 1.5 times the first relative dielectric constant.

### Technological Proposal 10

The semiconductor device according to Technological Proposal 8 or 9, wherein
a plurality of the third conductive members is provided, and
a part of the third insulating member is between one of the plurality of third conductive members and another one of the plurality of third conductive members.

### Technological Proposal 11

The semiconductor device according to Technological Proposal 1, wherein
the second insulating member further includes a second insulating portion, and
the second insulating portion is between the first conductive member and the second insulating region in the second direction.

### Technological Proposal 12

The semiconductor device according to Technological Proposal 11, wherein
a second insulating portion width along the second direction of the second insulating portion is greater than a second insulating region width in the second direction of the second insulating region.

### Technological Proposal 13

The semiconductor device according to Technological Proposal 11, wherein
a second insulating portion width along the second direction of the second insulating portion is less than a first insulating portion thickness in the first direction of the first insulating portion.

### Technological Proposal 14

The semiconductor device according to Technological Proposal 11, wherein
a direction from the fourth insulating region toward a part of the second insulating portion is along the second direction.

### Technological Proposal 15

The semiconductor device according to any one of Technological Proposals 11 to 14, further comprising:
a third conductive member; and
a third insulating member,
the third conductive member being between the first partial region and the second conductive member in the first direction,
at least a part of the third insulating member being between the third conductive member and the second conductive member,
a third relative dielectric constant of the third insulating member being greater than the first relative dielectric constant.

### Technological Proposal 16

The semiconductor device according to any one of Technological Proposals 1 to 15, wherein
the second relative dielectric constant is not less than 1.5 times the first relative dielectric constant.

### Technological Proposal 17

The semiconductor device according to any one of Technological Proposals 1 to 16, wherein
the second insulating member includes a first compound including at least one selected from the group consisting of Si₃N₄, Al₂O₃, TiO₂, Ta₂O₅, SrTiO₃, LiNbO₃, Nb₂O₅, LaCuO₃, Pr₂O₃, LaAlO₃, La₂O₃, ZrO₂, HfO₂, HfSiO₄, Ce₂O₃, CeO₂, Sm₂O₃, Y₂O₃, Lu₂O₃, BaO, CaO, MgO, ZrSiO₄, BaTiO₃, TiSiO₄, and ZrTiSiO.

### Technological Proposal 18

The semiconductor device according to any one of Technological Proposals 1 to 17, wherein
a first resistance value between the second conductive member and the first electrode, a second resistance value between the second conductive member and the second electrode, and a third resistance value between the second conductive member and the third electrode each are not less than 90 kΩ.

### Technological Proposal 19

The semiconductor device according to any one of Technological Proposals 1 to 18, wherein
the second relative dielectric constant is not less than 3.9 and not more than 67.8.

### Technological Proposal 20

The semiconductor device according to any one of Technological Proposals 1 to 19, comprising:
a support body including a first surface,
the first surface being along a plane including the first and second directions,
the first surface facing the semiconductor member,
the third electrode, the first conductive member, and the second conductive member extending along a third direction,
the third direction crossing the plane including the first and second directions.

According to embodiments, a semiconductor device can be provided in which characteristics can be improved.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as a semiconductor member, semiconductor regions, conductive members, electrodes, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode, a direction from the first electrode toward the second electrode being along a first direction;
a third electrode located between the first electrode and the second electrode in the first direction;
a first conductive member configured to be electrically connected with the second electrode, a position in the first direction of the first conductive member being between a first electrode position in the first direction of the first electrode and a third electrode position in the first direction of the third electrode;
a semiconductor member including a first semiconductor region and a second semiconductor region, the first semiconductor region and the second semiconductor region being of a first conductivity type, a second impurity concentration of the first conductivity type of the second semiconductor region being greater than a first impurity concentration of the first conductivity type of the first semiconductor region, the first semiconductor region including a first partial region and a second partial region, the first partial region being between the first electrode and the first conductive member in the first direction, a direction from the first conductive member toward the second partial region being along a second direction crossing the first direction, the second semiconductor region being between the second partial region and the second electrode in the first direction, a direction from the third electrode toward the second semiconductor region being along the second direction;
a second conductive member located between the first partial region and the first conductive member in the first direction, the second conductive member being electrically insulated from the second electrode;
a first insulating member including a first insulating region, a second insulating region, a third insulating region, and a fourth insulating region, at least a part of the first insulating region being between the third electrode and the semiconductor member, at least a part of the second insulating region being between the first conductive member and the semiconductor member, at least a part of the third insulating region being between the second conductive member and the semiconductor member, at least a part of the fourth insulating region being between the first conductive member and the third electrode; and
a second insulating member including a first insulating portion, the first insulating portion being between the second conductive member and the first conductive member, a second relative dielectric constant of the second insulating member being greater than a first relative dielectric constant of the first insulating member.

2. The semiconductor device according to claim 1, wherein
at least a part of the second electrode has a Schottky contact with the semiconductor member.

3. The semiconductor device according to claim 1, wherein
the semiconductor member further includes a third semiconductor region of a second conductivity type,
the third semiconductor region is between the second partial region and the second semiconductor region, and
a part of the first insulating region is between the third electrode and the third semiconductor region in the second direction.

4. The semiconductor device according to claim 1, wherein
a width along the second direction of the first insulating portion is less than a first width along the second direction of the first conductive member, and
the width along the second direction of the first insulating portion is less than a second width along the second direction of the second conductive member.

5. The semiconductor device according to claim 1, wherein
the first insulating member further includes a fifth insulating region, and
at least a part of the fifth insulating region is in at least one of
a first position between the first insulating portion and the first conductive member, or
a second position between the second conductive member and the first insulating portion.

6. The semiconductor device according to claim 1, wherein
a length along the first direction of the first conductive member is greater than a length along the first direction of the third electrode.

7. The semiconductor device according to claim 1, wherein
a width along the second direction of the first insulating region is less than a width along the second direction of the second insulating region.

8. The semiconductor device according to claim 1, further comprising:
a third conductive member; and
a third insulating member,
the third conductive member being between the first partial region and the second conductive member in the first direction,
at least a part of the third insulating member being between the third conductive member and the second conductive member,
a third relative dielectric constant of the third insulating member being greater than the first relative dielectric constant.

9. The semiconductor device according to claim 8, wherein
the third relative dielectric constant is not less than 1.5 times the first relative dielectric constant.

10. The semiconductor device according to claim 8, wherein
a plurality of the third conductive members is provided, and
a part of the third insulating member is between one of the plurality of third conductive members and another one of the plurality of third conductive members.

11. The semiconductor device according to claim 1, wherein
the second insulating member further includes a second insulating portion, and
the second insulating portion is between the first conductive member and the second insulating region in the second direction.

12. The semiconductor device according to claim 11, wherein
a second insulating portion width along the second direction of the second insulating portion is greater than a second insulating region width in the second direction of the second insulating region.

13. The semiconductor device according to claim 11, wherein
a second insulating portion width along the second direction of the second insulating portion is less than a first insulating portion thickness in the first direction of the first insulating portion.

14. The semiconductor device according to claim 11, wherein
a direction from the fourth insulating region toward a part of the second insulating portion is along the second direction.

15. The semiconductor device according to claim 11, further comprising:
a third conductive member; and
a third insulating member,
the third conductive member being between the first partial region and the second conductive member in the first direction,
at least a part of the third insulating member being between the third conductive member and the second conductive member,
a third relative dielectric constant of the third insulating member being greater than the first relative dielectric constant.

16. The semiconductor device according to claim 1, wherein
the second relative dielectric constant is not less than 1.5 times the first relative dielectric constant.

17. The semiconductor device according to claim 1, wherein
the second insulating member includes a first compound including at least one selected from the group consisting of Si₃N₄, Al₂O₃, TiO₂, Ta₂O₅, SrTiO₃, LiNbO₃, Nb₂O₅, LaCuO₃, Pr₂O₃, LaAlO₃, La₂O₃, ZrO₂, HfO₂, HfSiO₄, Ce₂O₃, CeO₂, Sm₂O₃, Y₂O₃, Lu₂O₃, BaO, CaO, MgO, ZrSiO₄, BaTiO₃, TiSiO₄, and ZrTiSiO.

18. The semiconductor device according to claim 1, wherein
a first resistance value between the second conductive member and the first electrode, a second resistance value between the second conductive member and the second electrode, and a third resistance value between the second conductive member and the third electrode each are not less than 90 kΩ.

19. The semiconductor device according to claim 1, wherein
the second relative dielectric constant is not less than 3.9 and not more than 67.8.

20. The semiconductor device according to claim 1, comprising:
a support body including a first surface,
the first surface being along a plane including the first and second directions,
the first surface facing the semiconductor member,
the third electrode, the first conductive member, and the second conductive member extending along a third direction,
the third direction crossing the plane including the first and second directions.
